(19) United States
(12) Patent Application Publication
(10) Pub. No.: US 2025/0295038 A1
(43) Pub. Date: Sep. 18, 2025

(54) METHOD FOR PRODUCING FERROELECTRIC THIN FILMS USING A SUBSTRATE WITH A POLARIZATION FIELD

(71) Applicant: National Cheng Kung University, Tainan City (TW)

(72) Inventors: CHUNG-LIN WU, Tainan City (TW); ZHEN-YOU LIN, Tainan City (TW); SHENG-SHIANG WONG, Tainan City (TW); YEN-FU HUANG, Tainan City (TW); PING-HUNG LI, Tainan City (TW); CHING-YU CHEN, Tainan City (TW)

(21) Appl. No.: 18/775,167

(22) Filed: Jul. 17, 2024

(30) Foreign Application Priority Data
Mar. 14, 2024 (TW) 113109473

(51) Int. Cl. H10N 50/01; H10N 50/85

(52) U.S. Cl. CPC H10N 50/01; H10N 50/85

(57) ABSTRACT

A method for producing ferroelectric thin films using a substrate capable of generating a polarization field is disclosed. This method involves providing a substrate that can produce an electric field effect on its surface, followed by growing a first thin film layer on this substrate through an epitaxial process, and then further growing a second thin film layer on the first thin film layer. The second thin film layer develops ferroelectric properties due to the electric field effect generated by the substrate's surface, causing two atomic layers within the second thin film layer to exhibit ferroelectric characteristics through misaligned stacking epitaxial growth. Based on the misaligned epitaxial growth of different numbers of atomic layers affecting the orientation and polarization direction of the ferroelectric regions within the second thin film layer, the material's ferroelectric characteristics can be precisely controlled without the need for external electric field application during the growth process.

### FIELD OF THE DISCLOSURE

The present invention pertains to the field of material science and nanotechnology, specifically to the synthesis and application of ferroelectric thin films.

### BACKGROUND OF THE INVENTION

Ferroelectric materials have long been a subject of intensive research due to their spontaneous electric polarization, which can be reversed by an applied electric field. This property has been utilized in various applications ranging from non-volatile memory to sensors and actuators. In recent years, research focus has shifted towards developing ferroelectric properties in two-dimensional (2D) materials, a breakthrough that could radically transform the miniaturization and performance of electronic components.

Traditionally, ferroelectric characteristics in thin films have been discovered in materials such as perovskite oxides. However, these materials often require complex fabrication processes and are not readily integrated into flexible or nano-scale electronic systems. Additionally, ferroelectric regions in such materials are typically limited in size, and the fabrication process often leads to the inclusion of impurities, which degrade the material's ferroelectric properties.

The emergence of Van der Waals materials, such as hexagonal boron nitride (h-BN), has opened up new possibilities. These materials can exhibit ferroelectric properties even at very thin thicknesses and can be stacked in various ways, offering the potential to create resettable electronic devices. Nevertheless, reliably producing and controlling ferroelectric properties in these 2D materials, especially over large areas suitable for commercial applications, remains a significant challenge.

Currently, two main techniques are primarily used in the production of 2D ferroelectric thin films:
1. The transfer method for 2D ferroelectric thin films involves using tape to peel off single layers of 2D material from bulk materials and transferring them onto a silicon dioxide substrate. Optical imaging stacking technology is then used to stack two layers of 2D materials in an AB configuration, thereby forming a ferroelectric thin film. However, this method faces challenges in achieving high success rates, realizing large-area ferroelectric regions, and maintaining chemical purity during the transfer process.
2. The growth method for 2D material thin films includes depositing hexagonal boron nitride (h-BN) on various substrates, such as sapphire, copper, gold, and highly oriented pyrolytic graphite. Although these methods demonstrate the ability to grow 2D material thin films on a wide range of substrates, the resulting h-BN films often lack ferroelectric properties, as evidenced by the AA′ stacking configuration shown in ARPES (Angle-Resolved Photoemission Spectroscopy) data.

Therefore, there is a need for improvement in the methods for producing 2D ferroelectric thin films to overcome the limitations of existing technologies. Specifically, there is an urgent demand for a scalable and efficient process that allows precise control over the film's ferroelectric characteristics, making it possible to produce high-quality ferroelectric thin films suitable for a wide range of applications.

### SUMMARY OF THE INVENTION

The present invention provides a novel method for producing ferroelectric thin films with ferroelectric properties, which not only overcomes the limitations of existing technologies but also advances the development of ferroelectric materials across various application domains. The invention focuses on using substrate engineering to produce a substrate with misaligned angles, thereby generating multiple steps on the substrate to induce an internal electric field. This field influences the growth and properties of the ferroelectric thin films, allowing for precise control over their ferroelectric characteristics during the epitaxial process without the need for an external electric field.

In the method of the present invention, the production of ferroelectric thin films includes the following steps. First, a substrate is provided, whose surface includes multiple steps formed by misaligned angles. Then, a first thin film layer is grown on the substrate through an epitaxial process, followed by the growth of a second thin film layer on the first thin film layer.

At least two atomic layers or molecular layers within the second thin film layer exhibit ferroelectric properties induced by the internal electric field generated by the substrate's steps. This method allows the grown ferroelectric thin films to have controllable layer numbers, regional orientations, and polarization directions, making them more suitable for a wide range of electronic applications.

In one embodiment, the substrate material, for example, is 4H-silicon carbide (4H—SiC), and the materials used for the first and second thin film layers are graphene and hexagonal boron nitride, respectively, with epitaxial conditions optimized to achieve the desired ferroelectric properties. Additionally, this method involves using techniques such as Piezoresponse Force Microscopy (PFM) to inspect the ferroelectric characteristics of the second thin film layer, to confirm the presence and arrangement direction of ferroelectric regions.

Overall, compared to existing methods and devices for producing ferroelectric thin films, the present invention offers several advantages, including:
1. Control over the ferroelectric properties of the films by generating a substrate with misaligned angles through substrate engineering, thereby creating multiple steps on the substrate. The internal electric field produced by the steps and the number of atomic layers within the second thin film layer can be used to control the ferroelectric properties of the film.
2. Simplification of the manufacturing process by eliminating the need for an external electric field during growth.
3. Improvement in the quality of the ferroelectric thin films, making them more suitable for a broad range of electronic applications.

In summary, the present invention represents a significant advancement in the field of ferroelectric materials, providing a more efficient, scalable, and flexible method and device for producing ferroelectric thin films with customizable characteristics.

### BRIEF DESCRIPTION OF THE DRAWINGS

The objects, spirits, and advantages of the preferred embodiments of the present disclosure will be readily understood by the accompanying drawings and detailed descriptions, wherein:

FIG. 1 illustrates the flowchart for preparing the substrate in one embodiment of the present invention.

FIG. 2 depicts the flowchart for the method of producing ferroelectric thin films in the embodiment.

FIGS. 3A to 3C show the three-dimensional schematic diagrams corresponding to the steps S210 to S230 described in FIG. 2.

FIGS. 4A and 4B display the role of piezoresponse force microscopy in analyzing the ferroelectric properties of double-layer and triple-layer h-BN thin films in the second thin film layer.

FIG. 5 is a sample captured using a transmission electron microscope.

FIG. 6 shows an example of the patternable functionality of the ferroelectric thin films produced in the embodiment.

FIG. 7 presents a theoretical simulation diagram of the formation energies for AA, AB, and BA stacking configurations in double-layer hexagonal boron nitride (h-BN) under an external electric field.

### DESCRIPTION OF THE PREFERRED EMBODIMENTS

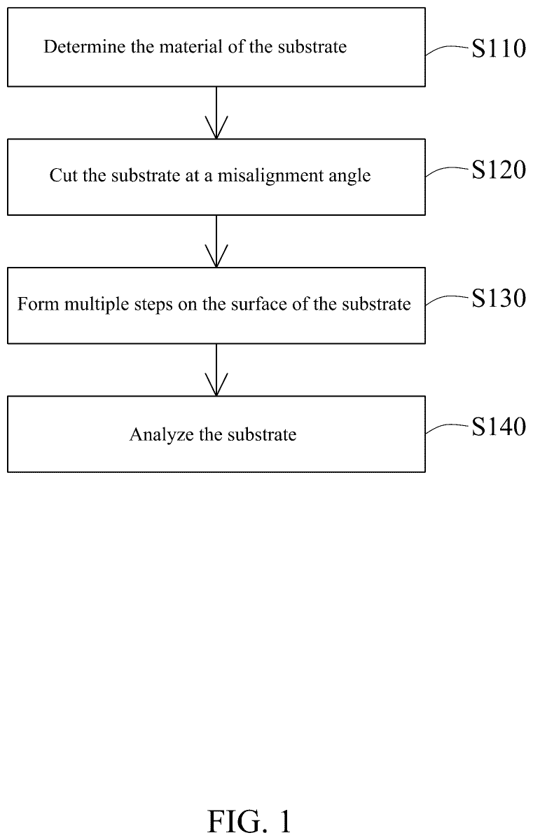

In this embodiment, the description begins with the preparation of the substrate, which plays a crucial role in the subsequent growth process of ferroelectric thin films with controllable properties. The characteristic feature of the substrate is its surface formed by multiple steps (also referred to as stairs or ledges) created by predetermined misaligned angles. These misaligned angles are key to inducing ferroelectric properties in the films grown on the substrate. Refer to FIG. 1, which illustrates the flowchart for preparing the substrate in this embodiment. Initially, as indicated in step S110, the material of the substrate is determined. In this embodiment, the substrate material is 4H-silicon carbide. Next, referring to step S120, to fabricate a substrate with misaligned angles, the 4H-silicon carbide substrate is cut in such a manner that the cutting line slightly deviates from the main crystal plane. This angle, known as the “misalignment angle,” typically ranges from 0.1 to 5 degrees in this embodiment. Those skilled in the art can select specific misalignment angles as needed to optimize step density and electric field strength.

Following the cutting process, as referred to in step S130, the cut surface appears rough and disordered. Etching is then performed in an inert gas environment (for example, argon) with a small amount of reductant (such as hydrogen) to remove oxides and other potential contaminants. The etching temperature is maintained within a range that promotes surface atom migration, evaporating carbon and silicon atoms to transform the originally rough surface into a structured step formation, typically between 1300° C. to 1550° C. This process not only removes surface contaminants but also regularizes the step structure, creating a uniform platform conducive to controlled film growth thereafter. In this embodiment, these steps are not merely surface features but play a significant role in subsequent processes, providing an internal electric field that influences the growth of subsequent thin films. The formation of steps due to the misalignment angle creates a height difference at the atomic plane, thereby creating a pattern of stair-like formations on the surface through etching. The height, width, and spacing of these steps can be controlled through the misalignment angle and subsequent etching and annealing treatments.

Next, referring to step S140, the substrate is analyzed to ensure that the characteristics of the steps meet the specifications required for the growth of ferroelectric thin films. Techniques such as Atomic Force Microscopy (AFM) or Scanning Electron Microscopy (SEM) can be used to inspect the uniformity and regularity of the steps, as well as to measure the height and width of the platforms.

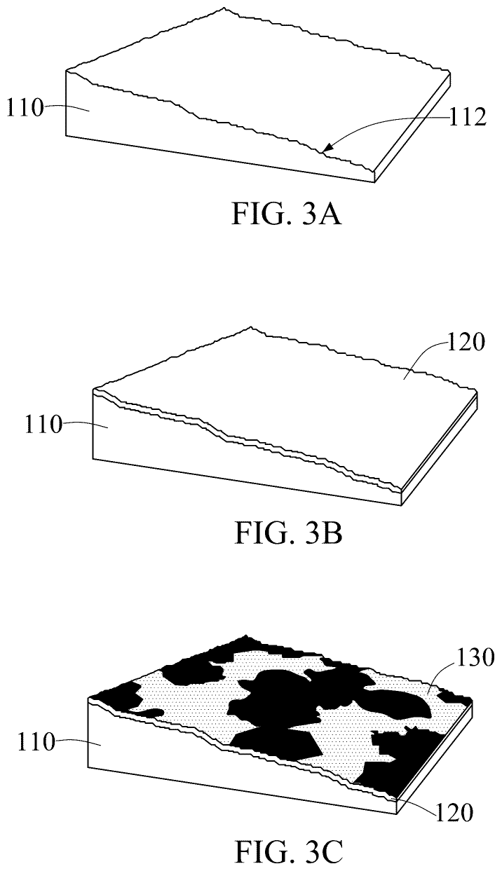

At this point, with the surface of substrate 110 having optimized multiple steps 112 (refer to FIG. 3A), the subsequent annealing and epitaxial thin film layer processes can begin. The careful preparation of substrate 110 ensures good growth conditions for the film layers, achieving the ideal ferroelectric thin film AB stacking.

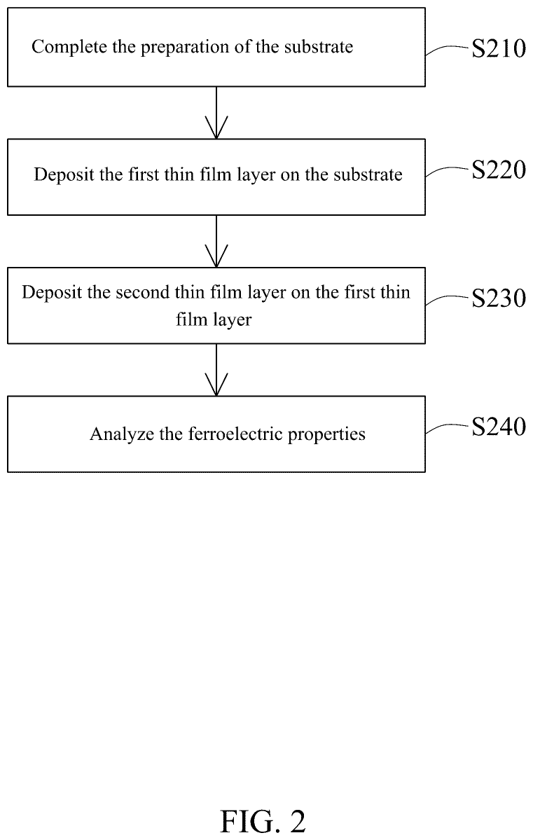

After the preparation of substrate 110 is complete, the subsequent annealing and epitaxial processes can commence. Refer concurrently to FIG. 2 and FIGS. 3A to 3C, where FIG. 2 illustrates the flowchart for the method of producing ferroelectric thin films in this embodiment, and FIGS. 3A to 3C represent the three-dimensional schematic diagrams corresponding to steps S210 to S230 described in FIG. 2. Initially, as shown in step S210 and FIG. 3A, the preparation of substrate 110 is completed, with its detailed process already described in FIG. 1. Then, as indicated in step S220 and FIG. 3B, the first thin film layer 120, which in this embodiment is a graphene film, is grown on substrate 110 via an epitaxial method. This step involves an annealing process to grow graphene on the substrate 110 that has been cut with a misaligned angle and etched from 4H-silicon carbide. In this embodiment, this is achieved through a high-temperature process where substrate 110 is placed in a carbon-rich environment under specific thermal treatment conditions, promoting the sublimation of silicon and the reconstruction of carbon structures on the silicon carbide surface to produce graphene. A voltage is applied to substrate 110 to generate resistive heat, bringing substrate 110 to the desired temperature range.

During this step S220, the temperature is controlled between 1300° C. to 1550° C. Once the temperature reaches this range, silicon atoms sublimate from the surface of silicon carbide, leaving behind a carbon-rich surface that is reconstructed into a graphene film. Graphene uniformly grows on substrate 110, which includes steps 112, forming continuous graphene films at the locations of steps 112. Ensuring the uniformity of the graphene film is crucial in this step because it serves as the foundation for the subsequent growth of the h-BN film. To ensure the quality and continuity of the graphene film, techniques such as Raman spectroscopy may be used in some embodiments to verify the number of graphene layers and the presence of any defects.

Next, as depicted in step S230 and FIG. 3C, multiple atomic layers within the second thin film layer 130 are grown epitaxially. In this embodiment, the second thin film layer 130 comprises a double-layer h-BN film grown on top of the first thin film layer 120 using a Molecular Beam Epitaxy System (MBE). The use of an MBE system is chosen for its precision, capable of growing high-purity films.

The MBE system operates under ultra-high vacuum conditions, where molecular or atomic beams are deposited onto the substrate, which is heated to a certain degree to allow atoms to have sufficient thermal energy to move to appropriate positions on the substrate surface and form a film. The pressure is typically below 10⁻⁹ torr to prevent contamination, ensuring the film grows in a clean environment. For the epitaxial growth of h-BN, the MBE system is equipped with a boron source and a nitrogen source. Boron sublimates from a solid source at high temperatures, while nitrogen gas is introduced into the chamber. A radio-frequency plasma (RF plasma) is often used to activate the nitrogen source, making it plasma, to increase reactivity. The epitaxial growth of hexagonal boron nitride occurs under nitrogen plasma and evaporated boron conditions, with the temperature of substrate 110 maintained between 900° C. to 1180° C. This temperature range allows for a better surface migration rate of boron and nitrogen atoms, which, guided by the internal electric field produced by the steps due to tip discharge effect, forms a well-structured AB stacking of h-BN film.

Refer concurrently to FIG. 7, which presents a theoretical simulation diagram of the formation energies for AA, AB, and BA stacking configurations in double-layer hexagonal boron nitride (h-BN) under an external electric field. This theoretical simulation explores the stacking configurations of double-layer h-BN. Under the influence of an applied electric field, the relative formation energies of AA, AB, and BA stackings are significantly different. In the simulation, the applied electric field mimics the “tip discharge effect” caused by the concentration of the electric field at sharp geometric shapes, such as the steps on the substrate's surface.

The simulation shown in FIG. 7 indicates that the AA stacking configuration, where the atoms of the upper layer directly align with the corresponding atoms of the lower layer, requires higher formation energy, suggesting that this structure is less stable under the conditions of an applied electric field. In contrast, AB and BA stacking introduce interlayer displacement, resulting in lower formation energy, indicating greater stability and the spontaneous polarization characteristics of ferroelectric materials. Notably, the AB stacking—where the top layer's atoms are positioned above the centers of the hexagons of the layer below—is shown to be the most energetically favorable. This indicates a natural tendency towards this type of stacking configuration when double-layer h-BN is epitaxially grown on the substrate's steps. This important insight provides a theoretical basis for the method of inducing ferroelectric properties in the films according to the present invention. Theoretically, the internal electric field introduced by the steps formed through substrate engineering precisely guides the epitaxial growth process of h-BN, favoring the AB stacking configuration.

In this embodiment, the molecular beam epitaxy system includes effusion cells for boron and nitrogen, a substrate heater, and various sensors to monitor pressure and temperature. The effusion cells are calibrated to provide a stable flux of boron and nitrogen, while the substrate heater ensures that the substrate remains within the temperature range suitable for h-BN growth. Real-time monitoring of the entire growth process is achieved, for example, through reflection high-energy electron diffraction (RHEED), which provides valuable information on the crystal structure and quality of the film during growth.

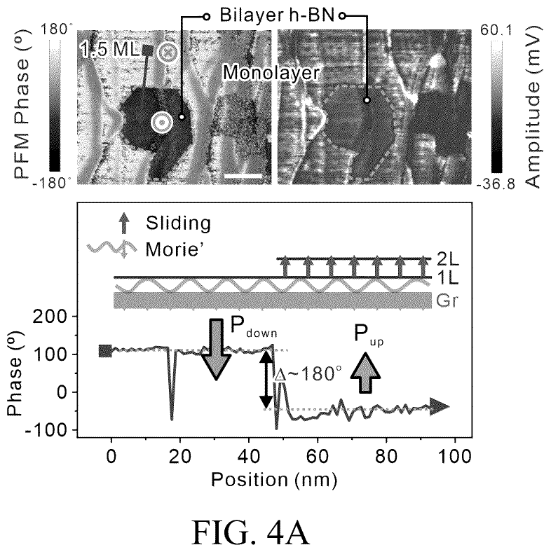

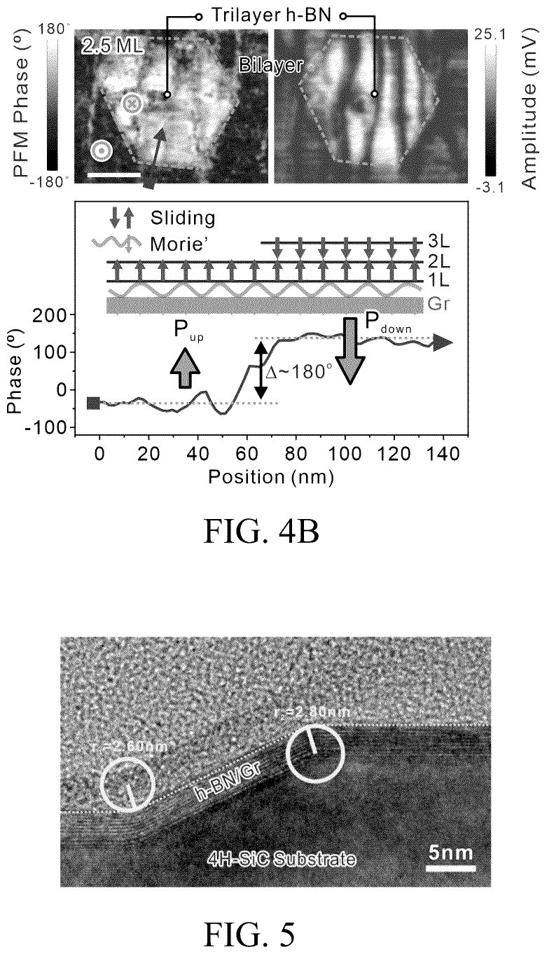

After completing steps S210 to S230, a ferroelectric thin film with distinct ferroelectric properties (i.e., the second thin film layer 130) is produced. At this point, step S240 can be executed to analyze the ferroelectric properties. In this step, techniques such as piezoresponse force microscopy can be used to confirm the ferroelectric properties produced by the second thin film layer 130 and to observe the arrangement direction of the ferroelectric polarization regions (as shown in FIGS. 4A and 4B). Piezoresponse force microscopy allows for the direct observation of the piezoelectric response of double-layer h-BN films in the second thin film layer under an applied electric field, providing definitive evidence of the material's ferroelectric properties. Such analysis not only confirms the successful induction of ferroelectric properties but also helps to map the arrangement direction of ferroelectric regions and evaluate whether the h-BN film is suitable for the fabrication of various electronic components in subsequent steps.

The substrate preparation and film epitaxial process described in FIGS. 1 and 2 aim to form ferroelectric thin films with distinct ferroelectric properties, a crucial aspect of this invention. Hence, a deeper exploration into the mechanisms and conditions for inducing and controlling ferroelectric properties in h-BN films (i.e., the second thin film layer 130) is provided.

The basis for inducing ferroelectric properties in h-BN films is the internal electric field generated by the steps 112 on substrate 110. These steps 112, formed by the misalignment angle of substrate 110, create a gradient of electric potential on the surface. When double-layer h-BN films are epitaxially grown on a graphene-covered substrate 110, this internal electric field influences the arrangement of h-BN molecules, promoting the formation of AB stacking. The AB stacking structure of h-BN films is key to the emergence of ferroelectric properties. In this structure, the boron and nitrogen atoms in the first layer and the nitrogen and boron atoms in the second layer form a polar structure. The internal electric field generated by the steps 112 energetically favors the arrangement of boron and nitrogen atoms into the desired structure, making stacking more facile. This precise control over the stacking order is achieved using substrate 110 with a misalignment angle.

Furthermore, the direction of ferroelectric polarization within the h-BN film can be controlled by fine-tuning several parameters during the growth process. These parameters include the number of layers in the h-BN film, the epitaxial temperature and time, and the characteristics of the steps 112 on substrate 110. By adjusting these factors, the invention can control the direction of ferroelectric polarization, allowing for fine-tuning of the material's ferroelectric properties for specific applications.

In this invention, verifying the characteristics of the ferroelectric film is essential. For this purpose, precise analytical techniques such as piezoresponse force microscopy are employed in this embodiment to confirm and observe the ferroelectric regions and their arrangement. Refer to FIGS. 4A and 4B, which demonstrate the critical reference role piezoresponse force microscopy plays in analyzing the ferroelectric properties of double-layer and triple-layer h-BN films. In FIGS. 4A and 4B, PFM phase images and corresponding amplitude signals for double-layer and triple-layer h-BN films are displayed. The phase signals in piezoresponse force microscopy can exhibit a 180-degree shift, representing a change in polarization direction. In the double-layer h-BN film, phase shift corresponds to an upward polarization vector (P_up), while in the triple-layer h-BN film, the polarization vector points downward (P_down). The PFM phase and amplitude data presented in FIGS. 4A and 4B, by showing a 180-degree phase difference characteristic of ferroelectric regions, confirm the ferroelectricity of the h-BN film and its controllability by layer number.

In FIGS. 4A and 4B, sliding refers to the lateral displacement of one h-BN layer relative to another, altering the material's symmetry and inducing a polarization field (P field) between the first and second layers of h-BN. Controlling this sliding and, thereby, the stacking configuration enables the intentional induction and control of ferroelectric properties within the material. Moiré patterns refer to the interference pattern created due to the mismatch in lattice constants between graphene and the overlying layer of h-BN. When two slightly mismatched or angled lattices overlap, they produce a larger-scale interference pattern, or Moiré pattern, generating a periodic potential that affects the material's electronic properties. Regarding ferroelectric properties, the Moiré pattern created when growing the first layer of h-BN on a graphene substrate could cause a change in potential, thereby inducing a polarization field. However, unlike the P field, which can be controlled by sliding the h-BN layers, the Moiré pattern—and any potential polarization field it may induce—is not easily adjustable after growth, as it is determined by the inherent lattice mismatch between graphene and h-BN.

Moreover, refer to FIG. 5, which shows a sample captured using a Transmission Electron Microscope (TEM). In FIG. 5, the black dashed lines and yellow circles are post-added by the inventors, where the area above the black dashed line is applied with amorphous ink used in TEM to delineate the sample boundaries, so the actual sample starts below the black line. FIG. 5 reveals that the substrate (indicated as 4H-SiC Substrate) indeed exhibits a stepped shape, with the h-BN and graphene films (indicated as h-BN/Gr) epitaxially grown on the substrate.

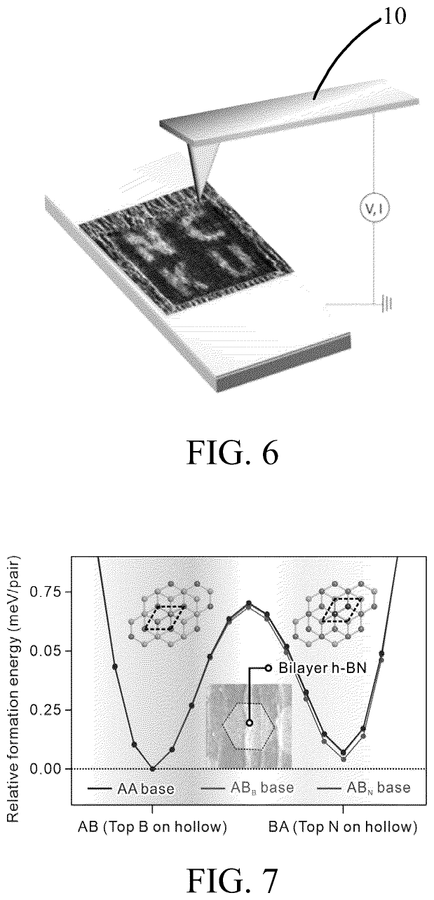

A significant feature of the ferroelectric thin films is their “patternability” when an external electric field is applied, which is very important for applications such as non-volatile memory devices. Herein, the inventor presents FIG. 6 as an example of implementing this patternable functionality, demonstrating the wide applicability of the ferroelectric thin films produced by the invention's method. In this embodiment, the h-BN film becomes patternable through the application of an external electric field using a contact mode atomic force microscope. This technique enables localized modification of the polarization state of the h-BN film. FIG. 6 showcases the ability to inscribe arbitrary patterns, such as the abbreviation “NCKU” for National Cheng Kung University in Taiwan. The external electric field can be finely tuned to flip the polarization direction in the h-BN film, achieving “writing” and “erasing” of patterns at the nanoscale. This process is reversible and can be repeated multiple times without degradation of the ferroelectric properties, which is crucial for data storage applications.

It should be noted that while the invention has been described in detail through the above embodiments, it is not limited to these configurations. The invention can adapt to various modifications and alternative forms, aiming to address the fundamental challenge of efficiently producing two-dimensional ferroelectric thin films. For instance, although graphene is used as the first thin film layer in the described embodiments, other materials like WSe2, silicene, or germanene could also be chosen. Moreover, while h-BN effectively demonstrates the ferroelectric properties described herein, other two-dimensional materials with similar properties, such as transition metal dichalcogenides (e.g., MoS2, WS2), perovskite oxides, or other layered structures exhibiting ferroelectric properties, could also replace h-BN. The choice of material will vary based on the required electrical properties, compatibility with the substrate material, and the needs of specific application fields. Furthermore, the substrate used for growing the ferroelectric thin films is not necessarily limited to silicon carbide; other substrates such as sapphire, silicon-based substrates, or flexible substrates could also be used, provided they can induce an internal electric field or possess the features necessary for the growth of ferroelectric thin films. The selection of substrates will vary based on lattice matching, thermal stability, economic considerations, and other factors.

Moreover, while molecular beam epitaxy systems can provide high accuracy and purity, other epitaxial or deposition techniques may also be suitable for certain applications. These alternative techniques include chemical vapor deposition (CVD), atomic layer deposition (ALD), and physical vapor deposition (PVD). Each technique has its advantages, and some may be more appropriate depending on the material, required film thickness, deposition rate, or production scale. For large-scale industrial production of ferroelectric thin films, methods more suited to mass production, such as scalable atomic layer deposition systems or large-area chemical vapor deposition reactors, may be adopted.

Furthermore, while the applications of ferroelectric thin films described in the above embodiments primarily focus on electronic device applications, the ferroelectric thin films produced by this invention could also likely be applied in other areas, such as optics, energy harvesting devices, and sensors. The flexibility in material and process selection broadens the potential impact of this invention across different technological fields.

Additionally, when creating steps on a substrate to facilitate the growth of ferroelectric thin films with specific alignment orientations or properties, various techniques can serve as alternatives or complements to the technique of forming misalignment angles on the substrate as mentioned above. For example, electron beam lithography can be used. In implementing this electron beam lithography technique, the substrate is coated with a resist that reacts to electron beam exposure. The electron beam lithography system then precisely exposes specific areas of the resist according to the pattern of the steps. After exposure, the substrate undergoes development to reveal the pattern, followed by an etching process. The etching process removes the substrate material in areas shielded by the resist during exposure, creating the required steps. Etching can be conducted using various methods, such as reactive ion etching (RIE), allowing precise control over the depth and shape of the steps.

Moreover, lithography combined with wet or dry etching processes is also a technique that can be used to create steps on the surface of a substrate. This process involves precisely creating a pattern of resist that acts as a mask during the etching process, removing specified areas of material to form step structures. Another technique is focused ion beam milling, which uses an ion beam to selectively remove material from the substrate, enabling the creation of steps or other structures with nanometer precision. Nanoimprint lithography involves deforming the surface of the substrate or resist layer to create nanoscale features, including steps, providing high uniformity and repeatability over large areas.

Chemical mechanical polishing is another method that can be used to create steps, selectively polishing away material from the substrate by using a mask or protective layer to control the removal locations. Laser ablation removal of material involves the use of high-power lasers, which can be precisely controlled to ablate specific areas of the substrate to form steps. Anisotropic etching, which removes material at different rates in different directions, can also be used to create steps, especially by exploiting the crystalline orientation of the substrate material. Additionally, selective area growth, although not a direct method for creating steps, can achieve a similar effect by growing material only in specific areas, thereby creating height differences akin to steps in functionality.

Moreover, substrates capable of generating an electric field effect on their surface include not only those with physical structures such as steps to induce an electric field but also substrates that inherently possess an electric field, such as polar substrates or those made from ferroelectric materials. These substrates introduce an intrinsic electric field or spontaneous polarization field, influencing the growth and properties of the ferroelectric thin films deposited on them. Polar substrates, especially those made from group-III nitrides like GaN, AlN, and InN, carry an inherent electric field due to their spontaneous polarization. This intrinsic electric field can effectively influence the deposition and properties of ferroelectric thin films, enabling control over ferroelectric characteristics during growth without the need for an external electric field. Additionally, substrates made from ferroelectric materials like bismuth ferrite (BFO), which possess a natural polarization field, can also be used. These materials can serve as substrates that inherently provide an electric field effect, beneficial for the subsequent growth of ferroelectric materials.

In conclusion, the other embodiments described above demonstrate the broad applicability of this invention in terms of materials, processes, and application scopes. The scope of this invention should not be limited to the described embodiments but is to be determined by the appended claims and their equivalents.

Overall, the description provided above details the method of producing ferroelectric thin films by this invention, particularly using hexagonal boron nitride as the ferroelectric material in the illustrated embodiment. This detailed description has been clarified through substrate preparation, epitaxial growth processes using molecular beam epitaxy systems, induction of ferroelectric properties, patternability of ferroelectric regions, and the versatility provided by various alternative implementations. The principles followed by this invention represent significant progress in the field of material science, especially in understanding and manipulating the ferroelectric properties of two-dimensional materials. The detailed methods for fabricating, measuring, and patterning ferroelectric thin films offer a clear roadmap from basic research to practical applications, harboring the potential to innovate the design and manufacturing of next-generation electronic devices.

This invention has a broad impact on the technology field, with application potential ranging from high-density memory, logic devices, to sensors and energy harvesting devices. It enables precise control over ferroelectric properties at the nanoscale, paving the way for the development of electronic products that require tunable, reversible polarization states.

1. A method for producing a ferroelectric thin film, comprising:
providing a substrate capable of generating an electric field effect on its surface;
growing a first thin film layer on the substrate through a first epitaxial process; and
growing a second thin film layer on the first thin film layer through a second epitaxial process, the second thin film layer comprising at least two atomic layers or molecular layers;
wherein the second thin film layer exhibits ferroelectric properties induced by the electric field generated by the substrate.

2. The method for producing a ferroelectric thin film of claim 1, wherein the surface of the substrate includes multiple steps formed by a substrate engineering process and the electric field is generated by the steps of the substrate.

3. The method for producing a ferroelectric thin film of claim 2, wherein the substrate engineering process includes:
preparing a substrate;
forming a substrate with a misaligned angle; and
etching and annealing the surface of the substrate formed by the misaligned angle.

4. The method for producing a ferroelectric thin film of claim 2, wherein the substrate comprises 4H-silicon carbide.

5. The method for producing a ferroelectric thin film of claim 1, wherein the first thin film layer comprises graphene.

6. The method for producing a ferroelectric thin film of claim 1, wherein the second thin film layer comprises hexagonal boron nitride.

7. The method for producing a ferroelectric thin film of claim 1, wherein the first epitaxial process used to grow the first thin film layer includes an etching process and an annealing process.

8. The method for producing a ferroelectric thin film of claim 7, wherein the etching process is conducted within a temperature range of 1300° C. to 1550° C., and the annealing process is conducted within a temperature range of 1000° C. to 1400° C.

9. The method for producing a ferroelectric thin film of claim 1, wherein the second epitaxial process used to grow the second thin film layer utilizes a molecular beam epitaxy system, and the molecular beam epitaxy system maintains an ultra-high vacuum.

10. The method for producing a ferroelectric thin film of claim 9, wherein the second epitaxial process used to grow the second thin film layer is conducted within a temperature range of 900° C. to 1180° C.

11. The method for producing a ferroelectric thin film of claim 1, further comprising controlling the number of layers in the second thin film layer to guide the ferroelectric polarization direction of the second thin film layer.

12. The method for producing a ferroelectric thin film of claim 1, further comprising using a piezoresponse force microscope to measure the ferroelectric properties of the second thin film layer, to confirm the presence and arrangement direction of ferroelectric regions.

13. The method for producing a ferroelectric thin film of claim 1, wherein the substrate includes a polar substrate with an inherent polarization field capable of inducing an electric field effect on its surface.

14. The method for producing a ferroelectric thin film of claim 13, wherein the material of the substrate includes a group consisting of gallium nitride (GaN), aluminum nitride (AlN), and indium nitride (InN).

15. The method for producing a ferroelectric thin film of claim 13, wherein the material of the substrate includes bismuth ferrite.
